(19) United States
(12) Patent Application Publication
(10) Pub. No.: US 2012/0235410 A1
(43) Pub. Date: Sep. 20, 2012

(54) LIGHTER THAN AIR WIND AND SOLAR ENERGY CONVERSION SYSTEM

(76) Inventor: Richard J. Serrano, Chula Vista, CA (US)

(21) Appl. No.: 13/048,828

(22) Filed: Mar. 15, 2011

(51) Int. Cl. H01L 31/052; B64B 1/50; G05D 1/00; F03D 9/00; H02P 9/04

(52) U.S. Cl. 290/50; 290/55; 701/3; 244/33

(57) ABSTRACT

An integrated solar and wind energy conversion system that is carried aloft by an aerostat/balloon, which is filled with lighter-than-air gas or hot air comprises solar panel array and wind turbine array to convert solar radiation and wind power into usable and renewable energy for on and/or off-grid application or storage. The solar panel array includes at least one of the flexible solar panel and spray on solar composite or combinations thereof. The present invention requires minimal land mass, can be deployed in remote areas, it can be deployed as permanent, semi-permanent, or temporary configurations. The present invention uses computers to automate many of the systems function for maximum energy harvesting. The present invention can be used both day and night.

### BACKGROUND OF THE INVENTION

1. Field of the Invention

The present invention relates generally to an integrated solar and wind energy conversion system and, more particularly, to an integrated solar and wind energy conversion system that is carried aloft by an aerostat/balloon, which is filled with lighter-than-air gas or hot air.

2. Description of Related Art

The solar and/or wind energy conversion systems are known in the art. Commercially available energy conversion systems generally require large amounts of land mass and/or area. Traditional solar or wind energy conversion systems are relatively area intensive and require transportation systems e.g. road, railway, truck to transport—the equipment and are generally not portable or easily deployable in remote OR heavily populated areas. They are maintenance-intensive due to more mechanical parts involved in the equipment setup. Violent storms and turbulence have been primarily responsible for wind turbine breakdown and destruction, making traditional wind turbines require constant maintenance. It is also difficult to fix and maintain equipment positioned atop of a tower. Traditional wind turbines are not generally self-sufficient or autonomous. Current solar systems are generally limited by their geometric nature and design e.g. square flat solar panels. Current wind turbines are generally limited to being installed upon masts or other structures with limited height. Most of traditional energy conversion system cannot be used both night and day. They generally do not display or have the ability to be as versatile as to be deployed in permanent, semi-permanent, or temporary configurations. Current commercially available systems do not employ a computer(s) to automate many of the systems functions for maximum energy harvesting and maintain the system within its safe operating parameters.

It is known that the amount of energy a wind turbine generates depends on the velocity of the wind. Higher elevation has higher wind velocity. It is known that wind power is proportional to velocity cubed. Traditional wind turbines either have high towers or are placed on high elevation ground sites to get enough wind velocity. This ground elevation dependency limits the sites where wind turbines are suitable for construction. Higher towers for the wind turbine can be constructed at sites of lower elevation however this greatly increases the cost of the tower construction. Moreover, a fixed height for the wind turbine is less efficient than a height adjustable wind turbine that can adjust itself to the right height for maximum wind velocity. In order to take advantage of the wind speed and the maximum exposure of solar radiation, efforts made to set up the energy conversion platform in high altitude are disclosed in the following patents. U.S. Pat. No. 4,073,516 to Kling (1978) discloses a tethered wind-driven floating power plant which includes a support body carrying at least one rotor assembly and a current generator coupled with the rotor. The support body is hollow and gas-filled to carry its own weight as well as the weight of the wind-driven power plant. U.S. Pat. No. 4,450,364 to Benoit (1984) discloses a lighter-than-air (LTA) wind energy conversion system wherein the LTA envelope carries a main rotor and electrical generator to take advantage of high wind speeds available at high altitudes. U.S. Pat. No. 5,645,248 to Campbell (1997) discloses a lighter than air apparatus which can be controlled and maneuvered while in flight. These patents do not utilize solar panel array(s) to provide additional energy source.

The efforts to incorporate solar energy and utilize the lighter-than-air gas to keep the energy conversion platform aloft are disclosed in U.S. Pat. No. 6,371,409 to Steele (2002) and U.S. Pat. No. 7,249,733 to Steele (2007). U.S. Pat. No. 6,371,409 to Steele (2002) discloses an at least partially buoyant vehicle which includes a gas-containing structure having solar panels for generating electrical power. U.S. Pat. No. 7,249,733 to Steele (2007) discloses a lighter-than-air aircraft, which includes a gas envelope for containing a buoyant gas, and a propulsion system carried by the gas envelope. A solar panel is carried by the gas envelope for powering the propulsion system when generating sufficient power. The power generated is for the powering of the system itself, not for producing energy for on or off grid use. These two patents do not use flexible solar panel so the coverage of the surface is limited and restrictive thus reducing the efficiency of solar energy conversion system. The systems also do not utilize wind energy or use computer automation to maximize the efficiency of the solar energy conversion system.

U.S. Pat. No. 7,821,147 to Du Bois discloses a portable, tow-able, buoyant hybrid renewable energy platform for producing and storing electrical energy using wind, water, and solar power, or a combination of these methods. The system does not take advantage of a high speed wind and solar energy in the high altitude, the energy harvesting may not be efficient.

The invention presented in the application is differentiated by the combination of technologies and the method of deploying/exposing, and applying these technologies for a more efficient manner in which to collect solar and wind energies and the use of a computer(s) and related software programs that automate many of the systems' functions for maximum exposure and/or safe storage of the system in adverse conditions, and the ability to be remotely deployed, operated, and monitored.

### SUMMARY OF THE INVENTION

The objective of the present invention is to provide an integrated solar and wind energy conversion system that requires a minimal amount of land mass or can be set up in a remote area or a highly populated area or can be deployed in a minimal amount of time.

The objective of the present invention is to provide an integrated solar and wind energy conversion system that can be deployed in a minimal amount of time.

The objective of the present invention is to provide an integrated solar and wind energy conversion system that uses a small percentage of the energy that is generated to operate itself without external energy input. The system is autonomous.

The objective of the present invention is to provide an integrated solar and wind energy conversion system that is not limited by the geometric nature of current systems.

The objective of the present invention is to provide an integrated solar and wind energy conversion system that can be deployed aloft into the atmosphere such that the system can receive maximum solar radiation and wind power.

The objective of the present invention is to provide an integrated solar and wind energy conversion system that can be used during both day and night.

The objective of the present invention is to provide an integrated solar and wind energy conversion system that utilizes a computer to automate many of the systems functions for maximum energy harvesting.

The objective of the present invention is to provide an integrated solar and wind energy conversion system that has flexibility and versatility as to be deployed in permanent, semi-permanent, or temporary configurations.

The objective of the present invention is to provide an integrated solar and wind energy conversion system that has the minimum amount of mechanical/moveable parts, thus, reducing the mechanical problems and the needs for frequent maintenance.

The objective of the present invention is to provide an integrated solar and wind energy conversion system that is scalable to fit the need, situation, and application.

The objective of the present invention is to provide an integrated solar and wind energy conversion system that reduces or completely reduces the need to install grid infrastructure (power lines, towers, roads, etc) to remote locations.

An unmanned lighter-than-air solar and wind energy conversion system (LTA-SWECS) comprises an aerostat/balloon, which is filled with a lighter than air gas and covered by a layer of solar panel array including at least one of the net type solar panel or spray-on solar composite; a connection hub located at the bottom of the aerostat/balloon, serves as a housing for data cables, electrical wiring, and gas refill tubes; the aerostat/balloon and the hub are supported by a tethering system (3 points), typically consisting of cables or ropes attached at the top to the hub and to a pulley system (3 points) on a mooring; a winch system attached to the pulley system to raise and lower the LTA-WSECS; a wind turbine array, which may be either attached to the hub in a cardinal configuration or to the tethering system in a vertical configuration. The LTA-WSECS further comprises a computer or computers and related software, a power inverter to convert direct current (dc) to alternate current (ac), and/or battery bank to store energy, and a charge controller/voltage regulator for avoiding overcharge of the power inverter and/or battery bank. The LTAWSECS utilizes the solar panel array installed on the aerostat/balloon and the wind turbine array as the platform to convert solar radiation and wind power into usable, renewable energy for on or off-grid applications or for storing in the battery bank.

Because the aerostat/balloon is filled with lighter than air gas or hot air, the aerostat/balloon resides aloft in the atmosphere; thus, there is no need for large land masses for the system to operate. The system produces both solar and wind energy during the daytime and wind energy during the night. Due to the geometric shape of the balloon the system exposes solar panels 360 degrees, no matter the sun's trajectory at whatever longitude or latitude. The system utilizes flexible solar panel or spray on solar composites which have less mechanical part compared to the traditional solar panel array, thus, it is not maintenance intensive. Both types of the solar panels provide flexibility such that the balloon can be inflated and put away in a container for storage or shipment to another place for deployment, thus, the system can be deployed in a minimal amount of time. In one embodiment, the wind turbines are removable, attached to the hub and/or the tethering system, so they can be detached for shipment. In another embodiment, the rotor blades may be folded to enable flexibility for shipment. The system provides flexibility and versatility as to be deployed in permanent, semi-permanent, or temporary configurations. In one embodiment, the aerostat/balloon further comprises an insulation layer between the external surface of the aerostat/balloon and the solar panel array to aid in sustaining the aerostat/balloon aloft in the atmosphere.

The system further comprises a computer and related software to automate many of the systems functions for maximum energy harvesting. The computer receives and analyzes meteorological data and controls and regulates the systems function including adjusting the altitude (raising or lowering) of the aerostat/balloon for maximum wind and solar energy. Since the system can receive the maximum solar and wind power and can be used day and night, the system can generate more energy than required to operate itself, thus, it is self-sufficient and autonomous.

The standard formula for calculating energy to be expected from a wind turbine expressed in metric terms is:

kWh=(½)(p)(V̂3)(A)(E)(H), where

“p” (normally “rho”, which looks like a small “p”) is the density of air
“V̂3” is the CUBE of the wind velocity
“A” is the area swept by the turbine rotors
“E” is the efficiency of capturing the kinetic energy that exists in a unit area of intercepted wind (such as “A”, above) for the given wind power capturing device at the given wind speed. This, in theory, can never exceed 59.3 percent, the “Betz Limit”.
“Power Coefficient” is the technical term used for this parameter in the wind industry.
“Power Coefficient” should not be confused with “Capacity Factor”, which is the proportion of energy actually captured compared to what would be captured if running at rated capacity full time. In theory, this could be 100 percent.
“H” is the number of hours for which the power was captured

However, since the wind velocity is constantly changing, the total kWh is an integration of this formula with respect to time, i.e. delta time instead of “H” in the above formula.

While the most important element in the above wind power math formula is the cube of the wind velocity, air density, which is a linear factor, does decrease with altitude. At 15,000 feet it is typically 57 percent of its density at sea level and at 30,000 feet it is typically about 31 percent of its density at sea level.

### Capacity Factor—Wind is More Persistent at High Altitudes:

It is common practice in the wind industry to talk in terms of rated capacity of wind turbines or total installed capacity at wind farms.

But this says nothing about how much energy is actually captured until “Capacity Factor” is brought in. Capacity Factor is the percentage of energy actually captured relative to what would be captured if the wind turbines were operating at full capacity all the time.

By far the biggest reason for not operating at capacity is that insufficient winds exist at the given site to generate at rated capacity. This is true at any altitude, but the percentage of the time is much less at high altitude.

In the year 1999 the average capacity factor for the wind turbines in California was 19.2 percent. Since then wind turbine efficiencies have improved, but ground based sites at which capacity factors are as high as 35 percent are difficult to find.

### Polymer Film for Solar Power Output Boost:

The power output of solar panels can be boosted by 10 percent just by applying a big transparent sticker to the front. The sticker is a polymer film embossed with microstructures that bend incoming sunlight. The result: the active materials in the panels absorb more light, and convert more of it into electricity. (This technology belongs to Genie Lens Technologies.) The technology is cheap and could lower the cost per watt of solar power produced by the LTA-SWECS.

The more important features of the invention have thus been outlined in order that the more detailed description that follows may be better understood and in order that the present contribution to the art may better be appreciated. Additional features of the invention will be described hereinafter and will form the subject matter of the claims that follow.

Before explaining at least one embodiment of the invention in detail, it is to be understood that the invention is not limited in its application to the details of construction and the arrangements of the components set forth in the following description or illustrated in the drawings. The invention is capable of other embodiments and of being practiced and carried out in various ways. Also it is to be understood that the phraseology and terminology employed herein are for the purpose of description and should not be regarded as limiting.

As such, those skilled in the art will appreciate that the concept, upon which this disclosure is based, may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

The foregoing has outlined, rather broadly, the preferred feature of the present invention so that those skilled in the art may better understand the detailed description of the invention that follows. Additional features of the invention will be described hereinafter that form the subject of the claims of the invention. Those skilled in the art should appreciate that they can readily use the disclosed concept and specific embodiment as a basis for designing or modifying other structures for carrying out the same purposes of the present invention and that such other structures do not depart from the spirit and scope of the invention in its broadest form.

### BRIEF DESCRIPTION OF THE DRAWINGS

Other aspects, features, and advantages of the present invention will become more fully apparent from the following detailed description, the appended claim, and the accompanying drawings in which similar elements are given similar reference numerals.

FIG. 1 is a schematic diagram of an embodiment of the lighter than air wind & solar energy conversion system (LTA-WSECS) according to the present invention.

FIG. 2 is a perspective view of an embodiment of the lighter than air wind & solar energy conversion system (LTA-WSECS) according to the present invention.

FIG. 3 is a top view of the hub and wind turbine array mounted on the hub in a cardinal configuration of one embodiment.

FIG. 4 is a perspective view of a wind turbine in one embodiment.

### DESCRIPTION OF THE PREFERRED EMBODIMENT

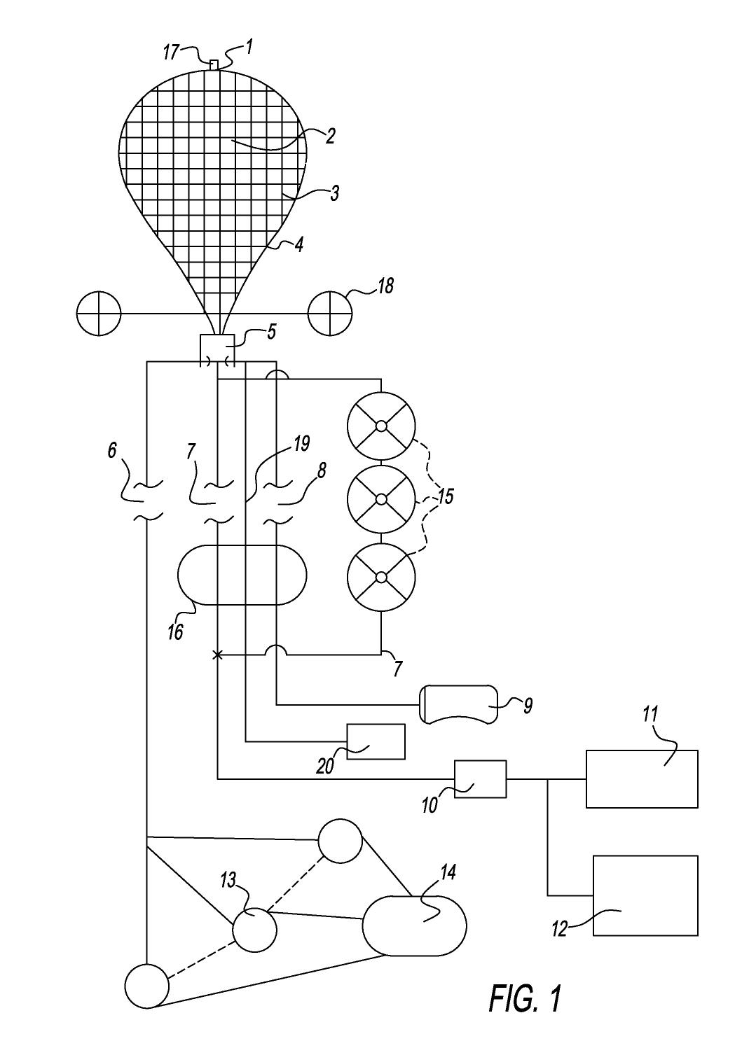

FIG. 1 is a schematic diagram of a lighter than air wind & solar energy conversion system (LTA-WSECS) 100 according to the present invention. This schematic diagram shows two different configurations of the wind turbines, the vertical configuration 15 and the horizontal cardinal configuration 18.

The LTA-WSECS 100 comprises a aerostat/balloon 1, which is filled with a lighter than air gas or hot air and covered by a layer of solar panel array 2; a connection hub 5 located at the bottom of the aerostat/balloon, serves as a housing for data cables 8, electrical wiring 7, and gas refill tubes 19; the aerostat/balloon 1 and the hub 5 are supported by a tethering system (3 points) 6, typically consisting of cables or ropes attached at the top to the hub 5 and to a pulley system (3 points) 13 on a mooring; a winch system 14 attached to the pulley system to raise and lower the LTA-WSECS 100; a wind turbine array 15, which may be either attached to the hub 5 in a horizontal arrangement or to the tether system 6 in a vertical fashion. The LTA-WSECS 100 further comprises a computer or computers 9 and related software, a power inverter 11 to convert direct current (dc) to alternate current (ac), and/or battery bank 12 to store energy, and a charge controller/voltage regulator 10 for avoiding overcharge of the power inverter 11 and/or battery bank 12. The LTA-WSECS 100 utilizes the solar panel array 2 installed on the aerostat/balloon 1 and the wind turbine array 15 or 18 as the platform to convert solar radiation and wind power into usable, renewable energy for on or off-grid applications or for storing in the battery bank 12.

The LTA-WSECS 100 further comprises one or more lightweight corrugated tubes made of polyethylene or other materials known in the art, attached to the hub, carry the electrical wiring 7, data cable(s) 8, and gas refill tube(s) 19 from the aerostat/balloon through the hub 5 to the ground. The electrical wiring 7 carry electrical energy generated by solar panel array and/or wind turbines to the inverter and/or battery bank. The Data cable(s) 8 provide data between computer, solar panel array, and wind turbine array. A gas refill tube(s) 19 is to provide the lighter than air gas to the aerostat/balloon. A wiring enclosure 16 may be included for organizing the electrical wiring, data cable(s), and gas refill tube(s).

The unmanned aerostat/balloon 1 is filled with lighter than air gas including but not limited to any of helium, hydrogen, hot air and future synthetic lighter than air gas, or the combinations thereof to provide the buoyancy of the system so that the system can reach high altitude into the atmosphere where the LTA-WSECS 100 can receive maximum and constant solar radiation and wind. The aerostat/balloon 1 may be of any shape and may be made of any suitable materials known in the art. The interior of the aerostat/balloon 1 may be coated with a leakage proof flexible rubber like material such as silicon or any materials known in the art to prevent the gas from leaking so that the system can be sustained aloft. A layer of solar panel array 2, including at least one of a net type array of flexible solar panels or a spray on solar composites or combinations thereof, is installed on the exterior surface of the aerostat/balloon 1 and is connected to a power inverter 11 and/or battery bank 12 via electrical wiring 7. Optionally, a charge controller/voltage regulator 10 may be installed before the power inverter 11 or batter bank 12 to avoid voltage overcharge. The flexible solar panels include but are not limited to flexible thin-film cells and modules, one of the commercially available flexible module uses amorphous silicon triple junction (from Uni-solar). The spray-on solar composite is a recently developed technology; it is based on nanotechnology and can be sprayed on the surface of the aerostat/balloon. Such material may convert infrared of solar radiation to usable energy. Unlike the current solar systems such as square flat solar panels of which efficiency is limited by the geometric shape; both the flexible solar panels and spray-on solar composite provide flexibility to adapt to the geometric shape of a aerostat/balloon so that the LTA-WSECS 100 can exposes solar panels 360 degree thus it doesn't matter what the sun's trajectory is.

In operation, during the daylight, the solar panel array 2 receives the solar radiation and converts some solar radiation into energy for on or off-grid application 20 or for storage in the battery 12. The heat produced by the energy converting process (photovoltaic effect) of the solar panel array 2 and the heat from solar radiation may diffuse/pass through the panels 2 and the external surface of the aerostat/balloon 1 and is trapped within the aerostat/balloon 1 thus heating the air or gas therein. As the heated air/gas expands and becomes lighter it flows toward the top of the aerostat/balloon 1 and is displaced out of the aerostat/balloon 1 through the one way valve 17 at the very top center of the aerostat/balloon 1 by gas/air entering the aerostat/balloon through the gas refill tube 19 from the gas/air supply 20.

An optional insulation layer 3 may be placed between the solar panel array 2 and the external surface of the aerostat/balloon 1 to absorb heat created by the photovoltaic process and channel such heat to within the aerostat/balloon 1 via a ducting system incorporated into the insulation to produce hot air for the aerostat/balloon's 1 sustainment aloft and fed through the one way valve 17 attached at the very top center of the aerostat/balloon 1, taking advantage of heat's natural tendency to rise. The insulation layer 3 may be made of polyester or polyimide film or any materials known in the art. The insulation layer 3 may not be needed considering the passive cooling of the solar panels 2 provided by the cool temperatures at high altitude.

A pressure sensor/probe 4 may be installed within the balloon/aerostat 1 or the hub 5 to measure the amount of pressure within the balloon/aerostat 1 and communicate such information to the computer 9 through the data cable 8 to control the critical pressure within the balloon/aerostat 1.

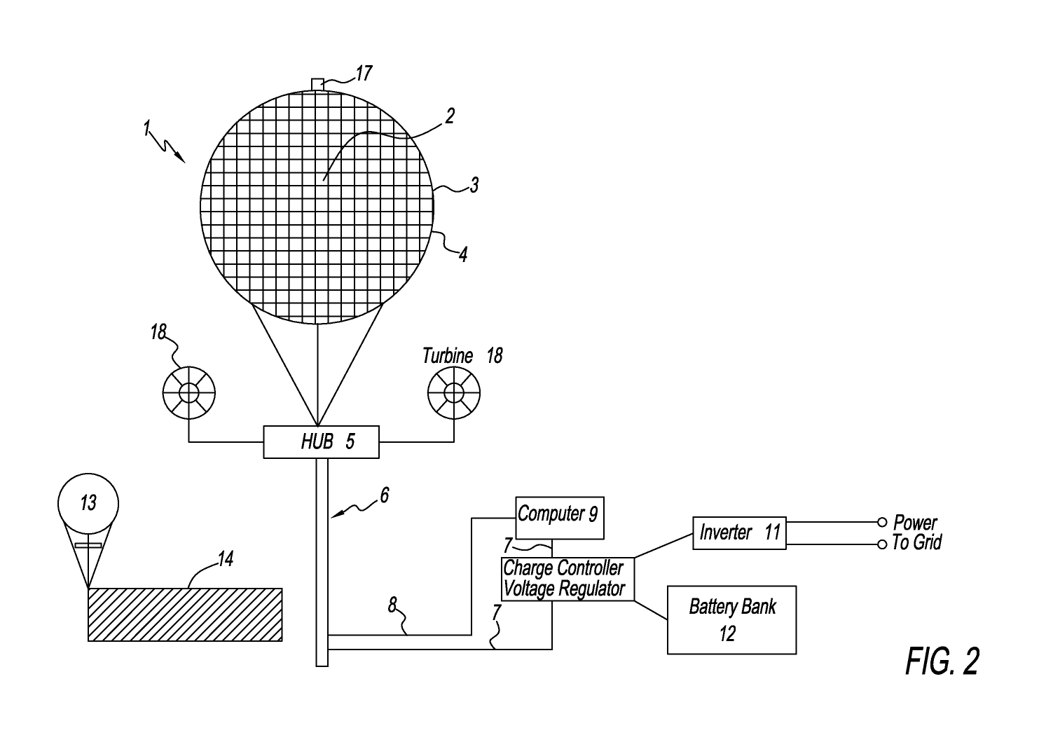

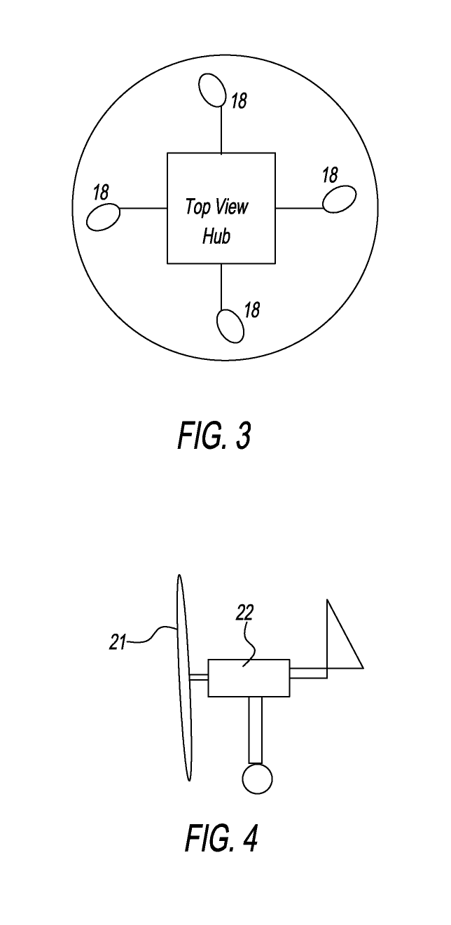

Using wind turbines to convert wind energy to usable and renewable energy is known in the art. The wind turbine array in the present invention includes at least one wind turbine. The wind turbine array including two turbines mounted on the hub in a cardinal configuration 18 and/or three turbines attached to the tethering system in a vertical configuration 15 are shown in FIG. 1. The wind turbines attached to the tethering system are preferably small in size. FIG. 2 shows a perspective of LTA-WSECS 100 with the wind turbines 18 installed on the hub 5 in a cardinal configuration. The preferred embodiment of the system has four wind turbines in a cardinal configuration. The top view of such wind turbine array is shown in FIG. 3. The wind turbine 15 or 18 in the present invention can refer to any suitable apparatus capable of converting kinetic energy from wind into electrical energy in an optimum capacity.

Typically, a wind turbine 15 or 18 comprises a rotor component including a rotor, a plurality of rotor blades, generator component, and structural components. The rotor component (rotor 22 and blades 21) converts the kinetic energy from the wind into mechanical energy. The generator component inside the wind turbine converts the mechanical energy generated by the rotor into electrical energy which travels through electrical wiring 7 to the current controller/voltage regulator 10 and to the inverter 11. Ultimately, the alternate current produced can be used for on or off-grid application or for storage in the battery 12. The computer 9 and related software also control the wind turbine array 15 or 18. The illustrated example shown in FIG. 4 is the horizontal axis wind turbines (HAWT) type wherein there is a need to orient their rotors into and out of the wind and they achieve that by means of passive or active yaw systems. One or more, preferably three rotor blades 21 may be included in a wind turbine. Rotor blades 21 can be of any suitable shape. Some examples of suitable shapes include curved, scooped, U-shaped, V-shaped, or other shapes. Rotor blades 21 can be made from a combination of glass and carbon-fiber-reinforced plastics. In another embodiment where the wind turbine is the vertical axis wind turbines (VAWT) which does not need a yaw system since their vertical rotors can face the wind from any direction and only their self rotation gives the blades a clear direction of the air flow.

The force, direction, and incidence of low-altitude winds dependent on geographic environment factors and are subject to considerable variations. High-altitude winds are significantly steadier as regards to their intensity and direction than low altitude winds. However, traditional wind-driven turbines on a tower are unable to utilize the high-altitude winds. The present invention, LTA-WSECS 100 utilizes the balloon/aerostat 1 to bring the wind turbines 18 to high altitude, to take advantage of the constant and high wind speed.

A computer 9 and related software automate many of the systems' functions for maximum energy harvesting, and more specifically providing control over the height or orientation adjustment of the system 100 to suit maximum efficiency exposure.

In one embodiment wherein a wind gauge (e.g. an anemometer) which is any suitable instrument for measuring the speed and the direction of the wind or a light sensor which is any suitable instrument for measuring the light intensity sends the data they collect to the computer 9 and related software which automatically adjust the height of the system LTA-WSECS 100 for maximum efficiency exposure of wind speed and solar radiation. The computer 9 also monitors and regulates the amount of gas or hot air within the balloon/aerostat 1 by analyzing the data collected from the pressure sensor 4 within the balloon/aerostat 1, so that it can adjust (raise or lower) the altitude of balloon/aerostat 1 to suit maximum efficiency. The computer 9 interprets meteorological data to initiate an automated process that raises or lowers the system 100 to ideal height of wind velocity and solar exposure or to completely lower and stow the system 100 in case of adverse weather conditions such as thunder & lightning storms via the Pulley 13 and Winch 14 Systems.

The system LTA-WSECS 100 further comprises a containing device such as a box or other type of container to provide for the self-containment, portability, shipping, rapid deployment of the LTA-WSECS 100. Both types of the solar panels 2 provide flexibility such that the aerostat/balloon can be deflated and put away in a container for storage or shipment to another place for deployment, the system can be easily deployable in remote or heavily populated areas in a minimal amount of time. In one embodiment, the wind turbines 15, 18 are removable and attached to the hub 5 and/or the tethering system 6, so they can be detached for shipment. In another embodiment, the rotor blades 21 may be folded to enable flexibility for shipment. The system provides flexibility and versatility as to be deployed in permanent, semi-permanent, or temporary configurations.

The system LTA-WSECS 100 uses a small percentage of the energy it produces for its function, eliminating the use of external power source. It is self-sufficient/autonomous in that the output energy is greater than the self provided input energy consumed to provide output energy. This system LTA-WSECS 100 requires very little maintenance to maintain operational status for longer periods of time due to the minimum amount of mechanical/moveable parts found in other systems.

While there have been shown and described and pointed out the fundamental novel features of the invention as applied to the preferred embodiments, it will be understood that the foregoing is considered as illustrative only of the principles of the invention and not intended to be exhaustive or to limit the invention to the precise forms disclosed. Obvious modifications or variations are possible in light of the above teachings. The embodiments discussed were chosen and described to provide the best illustration of the principles of the invention and its practical application to enable one of ordinary skill in the art to utilize the invention in various embodiments and with various modifications as are suited to the particular use contemplated All such modifications and variations are within the scope of the invention as determined by the appended claims when interpreted in accordance with the breadth to which they are entitled.

What is claimed is:

1. A lighter than air wind and solar energy conversion system comprising:
a. an aerostat/balloon filled with a lighter-than-air gas, internally coated with a leakage proof material, and externally covered with a layer of solar panel array, the aerostat/balloon contains a pressure sensor/probe inside;
b. a wind turbine array;
c. a connection hub installed at the base of the aerostat/balloon to provide a housing for all electrical connections, data cable connections, pass-through for gas refill tube;
d. a pulley system located on the ground;
e. a tethering system attached at the top to the hub and to the pulley system;
f. a charge controller/voltage regulator prevents over voltage.
g. an inverter to convert dc power to ac power;
h. a plurality of electrical wiring to carry power from the solar panel array and the wind turbine array to the power inverter; and
i. a computer and related software program that automates the system

2. The energy conversion system of claim 1, wherein the solar panel array including at least one net type array of flexible solar panels and a spray on solar collecting composite.

3. The energy conversion system of claim 1, wherein the aerostat/balloon further has an insulation layer between the solar panel array layer and the external surface of the aerostat/balloon for absorbing heat created by the process of energy conversion by the solar panels.

4. The energy conversion system of claim 1, wherein the wind turbines are attached to one or more of the tethers in a vertical configuration.

5. The energy conversion system of claim 1, wherein the wind turbines are mounted on the hub in a cardinal configuration.

6. The energy conversion system of claim 1 further comprises a winch system attached to the pulley system to raise and lower the energy conversion system.

7. The energy conversion system of claim 1 further comprises a battery bank to store energy;

8. The energy conversion system of claim 1 wherein the computer and related software interprets meteorological data to initiate an automated process that raises or lowers the system to ideal height of wind velocity and/or solar exposure.

9. The energy conversion system of claim 1 wherein the computer and related software monitor and regulate the amount of lift gas within the aerostat/balloon and initiate an automated process to provide more or less lift gas to raise or lower the system to suit maximum efficiency exposure.

10. The energy conversion system of claim 1 further comprises a containing device such as a box or other type of container providing for the self-containment, portability, shipping, rapid deployment of the system.

11. The energy conversion system of claim 1 wherein the data cable(s) provide data between computer and pressure sensor, solar panel array, wind turbine array.

12. The energy conversion system of claim 1 wherein the gas refill tube(s) transports the lighter than air gas to aerostat/balloon.

13. The energy conversion system of claim 11 wherein the lighter than air gas can be helium, hydrogen, hot air, a combination of, or any future lighter than air gas that may be synthetically produced.

14. A lighter than air wind and solar energy conversion system comprising:
a. an aerostat/balloon filled with a lighter-than-air gas, internally coated with a leakage proof material, and externally covered with a layer of solar panel array including at least one net type array of flexible solar panels and a spray on solar collecting composite, the aerostat/balloon contains a pressure sensor/probe inside;
b. a wind turbine array;
c. a connection hub installed at the base of the aerostat/balloon to provide a housing for all electrical connections, data cable connections, pass-through for gas refill tube;
d. a pulley system and a winch system located on the ground;
e. a tethering system attached at the top to the hub and to the pulley system;
f. a charge controller/voltage regulator prevents over voltage.
g. an inverter to convert dc power to ac power;
h. a battery bank to store energy;
i. a plurality of electrical wiring to carry power from the solar panel array and the wind turbine array to the power inverter and/or the battery bank;
j. a computer and related software program that automates the system, the computer and related software interprets meteorological data to initiate an automated process that raises or lowers the system to ideal height of wind velocity and/or solar exposure;
k. a containing device such as a box or other type of container providing for the self-containment, portability, shipping, rapid deployment of the system; and
l. wherein the wind turbines are attached to one or more of the tethers in a vertical configuration and/or mounted on the hub in a cardinal configuration; the lighter than air gas include at least one of the gas, helium, hydrogen, air, or the combinations thereof.

15. The energy conversion system of claim 14, wherein the aerostat/balloon further has an insulation layer between the solar panel array layer and the external surface of the aerostat/balloon for absorbing the heat created by the process of energy conversion by the solar panels.
